(19) United States
(12) Patent Application Publication
(10) Pub. No.: US 2008/0083981 A1
(43) Pub. Date: Apr. 10, 2008

(54) Thermally Enhanced BGA Packages and Methods

(76) Inventors: Matthew D. Romig, Richardson, TX (US); Thomas Mathew, Irving, TX (US)

Correspondence Address: TEXAS INSTRUMENTS INCORPORATED, P O BOX 655474, M/S 3999, DALLAS, TX, 75265, US

(21) Appl. No.: 11/422,863

(22) Filed: Jun. 7, 2006

(51) Int. Cl. H01L 23/34; H01L 21/00

(52) U.S. Cl. 257/707; 257/713; 438/122

(57) ABSTRACT

BGA packages have thermal properties which are enhanced by a heat channel through the substrate. Solder ball attachment points are provided at the surface of the heat channel for receiving solder balls. A BGA includes an IC operably coupled to a substrate having a top surface for receiving the IC and a bottom surface defining the perimeter of the package bottom. An encapsulant encloses the IC and at least a portion of the top surface of the substrate, defining the top and sides of the package. The substrate includes a heat channel aperture for receiving heat channel having a surface proximal to the IC and having a patterned opposing surface defining at least an interior portion of the package bottom and coupling to solder balls. Methods for assembling packages are disclosed in which a substrate is provided with a heat channel aperture and the heat channel is placed therein.

### TECHNICAL FIELD

The invention relates to electronic semiconductor devices and manufacturing. More particularly, the invention relates to surface-mount BGA-packaged semiconductor devices and to methods for the manufacture of the same.

### BACKGROUND OF THE INVENTION

The ball grid array (BGA) is a well-known type of surface-mount package that utilizes an array of metallic nodules, often denominated “solder balls” although they are not necessarily spherical, as means for providing external electrical connections. The solder balls are attached to a layered substrate at the bottom side of the package. The die, or integrated circuit (IC) chip of the BGA is connected to the substrate commonly either by wirebond or flip-chip connections. The layered substrate of a BGA has internal conductive paths that electrically connect the chip bonds to the ball array. This substrate is typically encapsulated with a plastic mold or glob top to form the top of the package. Typically a BGA, or PBGA (plastic ball grid array), a type of BGA that uses a plastic or organic material for the substrate construction, is mounted onto a printed circuit board (PCB) and used in applications requiring high reliability. For convenience, the term BGA is used herein to refer to both BGAs and PBGAs unless noted otherwise. In conventional surface-mount type BGA, a semiconductor chip is mounted on a substrate with an adhesive material. Bond wires couple contact pads on the chip with contact pads incorporated into the surface of the substrate. An encapsulant material forms a protective covering over the chip, bond wires, and some or all of the substrate. Solder balls are attached at predetermined contact points, such as ball attachment holes on the bottom surface of the substrate disposed in an array for mounting on a printed circuit board (PCB).

An advantage of the BGA or PBGA for integrated circuit (IC) packaging is its high interconnection density, i.e., the number of balls per given package volume is high. All packages have drawbacks, however, and the BGA is no exception. The high density of the BGA which makes it desirable for many applications can lead to a concentration of excess heat generated during operation of the circuitry. In general, the semiconductor chip in the packaged device generates heat when operated and cools when inactive. Due to the changes in temperature, the BGA package as a whole tends to thermally expand and contract. However, since in many cases the thermal expansion behavior of the package, its internal components, e.g., chip, substrate, and PCB differ, stresses can occur at the connecting solder balls, or within the layers of the PCB, or among the components of the package.

In general, the excess heat making its departure from a BGA package common in the arts may be understood in terms of following three thermal paths. Heat may travel from the chip through the top of the package. This is typically a relatively poor heat path due to inherent heat resistance of the encapsulant material, although heat conduction may sometimes be improved by the use of heat-conductive mold compound material, the inclusion of a heat spreader or external heat sink, or by using a thin mold cap. Another thermal path is in the plane of the substrate. This can be a better heat path than through the encapsulant, particularly in packages with thick substrates, but in some instances may be insufficient. The most direct thermal path, from the chip though the substrate, is generally the most efficient and is sometimes improved by the addition of thermal vias or thermal BGA balls designed to increase heat conduction away from the chip and substrate respectively. These improvements are necessarily limited by the available area and are not sufficient in all cases however, leaving a need for thermally enhanced BGA packages.

To further address the problem of dissipating excess heat, BGA-packaged semiconductor devices are known in the arts which are characterized by a heat spreader interposed between the semiconductor chip and the PCB. The heat spreader is designed to conduct heat way from the semiconductor chip in order to reduce thermally induced stress and increase package and IC reliability. The heat spreader is typically made from copper, nickel, or other metals selected for their heat conductive properties. This technology, however, has its own problems. The primary problem is related to assembly of the package onto the PCB. Manufacturing and interposing the heat spreader between the semiconductor chip and the PCB complicates production procedures, resulting in increased costs. Also, there are various challenges to attaching the heat spreader to the substrate, and in sealing the junctions between the heat spreader, chip, and substrate. Also, due to rigid attachment of the heat spreader to the PCB, there may be a degradation in reliability of the device due to the effects of thermally-induced stresses. Additionally, although it is desirable to make the heat spreader large in order to dissipate heat more effectively, larger sizes can lead to further problems such as increased susceptibility to warpage.

Due to these and other problems, it would be useful and advantageous to provide surface-mountable semiconductor packages, such as for example BGA and PBGA packages, with improved thermal conduction properties, and to provide improved methods for manufacturing and using the same efficiently within the context of existing assembly processes.

### SUMMARY OF THE INVENTION

In carrying out the principles of the present invention, in accordance with preferred embodiments thereof, packaged BGA devices are provided with improved thermal paths for removing excess heat from the chip using methods adapted for economical use with existing manufacturing processes.

According to one aspect of the invention, a BGA package of the invention includes an IC operably coupled to a substrate. The IC and at least a portion of the top surface of the substrate are encapsulated and thus the top, bottom, and sides of the package are defined. A heat channel provides a heat-conducting path from the IC to the bottom surface of the package. A heat channel element originates at the IC and terminates at the bottom surface of the package and is patterned for receiving solder balls.

According to another aspect of the invention, in an example of a preferred embodiment, a BGA package of the invention includes heat a channel element made from silicon.

According to yet another aspect of the invention, a BGA package according to the invention has a substrate with a heat channel aperture for receiving the heat channel element and providing a direct passage from the bottom surface of the IC to the bottom surface of the package. The heat channel element material matches the die material and is patterned for solder ball attachment.

According to still another aspect of the invention, in an example of a preferred method for assembling a thermally enhanced BGA package, a substrate having a heat channel aperture is provided and a heat channel element is placed in the heat channel aperture. An IC is placed adjacent to a first surface of the heat channel element and operably coupled to the substrate. The heat channel element has a second surface patterned for solder ball attachment and provides a direct heat path from the IC.

According to another aspect of the invention, in an example of a preferred embodiment, the method for assembling a thermally enhanced BGA package includes the step of taping the substrate and heat channel element in their relative positions during assembly of the package.

The invention has advantages including but not limited to providing an improved thermal path for the egress of heat from a packaged semiconductor device in a package format which is easily integrated into typical end user systems. This and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cut-away side view of an example of a preferred embodiment of a BGA according to the invention;

FIG. 2A is a cut-away side view showing an early step in an example of a method of manufacturing a BGA of FIG. 1 according to a preferred embodiment of the invention;

FIG. 2B is a cut-away side view showing a further step in the method of manufacturing a BGA of FIG. 1 according to a preferred embodiment of the invention;

FIG. 2C is a cut-away side view showing an additional step in the method of manufacturing a BGA of FIG. 1 according to a preferred embodiment of the invention;

FIG. 2D is a cut-away side view showing a step in the method of manufacturing a BGA of FIG. 1 according to a preferred embodiment of the invention;

FIG. 2E is a cut-away side view showing another step in the method of manufacturing a BGA of FIG. 1 according to a preferred embodiment of the invention;

FIG. 2F is a cut-away side view showing a further step in the method of manufacturing a BGA of FIG. 1 according to a preferred embodiment of the invention;

FIG. 2G is a cut-away side view showing a step in the method of manufacturing a BGA of FIG. 1 according to a preferred embodiment of the invention;

FIG. 2H is a cut-away side view showing one of the final steps in the method of manufacturing a BGA of FIG. 1 according to a preferred embodiment of the invention;

FIG. 21 is a cut-away side view illustrating an example of the use of a completed BGA packaged device according to a preferred embodiment of the invention; and

FIG. 3 is a process flow diagram showing steps in an example of a preferred method of assembling a BGA according to the invention.

References in the detailed description correspond to like references in the various drawings unless otherwise noted. Descriptive and directional terms used in the written description such as top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

In general, the invention enhances the thermal path from the IC to the bottom of the BGA package, e.g., to an attached PCB, with a much higher-conductivity path by providing a heat channel element made from material favorable for the conduction of heat, preferably silicon. The heat channel element is configured to accept solder ball attachment on its bottom surface, preferably masked and patterned in the manner of the substrate, thus providing a good thermal path from the IC to the PCB. The devices and methods of the invention may be implemented using cost-effective modifications to standard assembly processes.

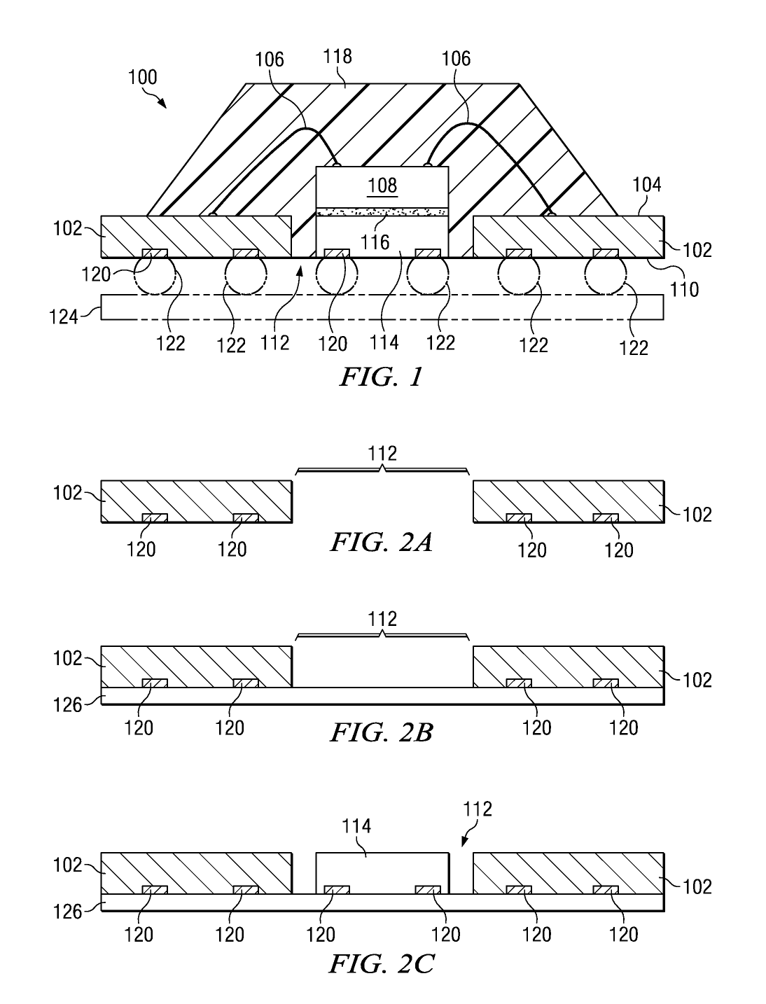

Now referring primarily to FIG. 1, an example of a preferred embodiment of a BGA package 100 according to the invention is shown in a cut-away side view. A semiconductor substrate 102 provides the foundation of the package 100 as generally understood in the art. The substrate 102 carries interconnecting circuitry (not shown) and the top surface 104 of the substrate 102 accepts bond wires 106 as typically found in the art, completing electrical connections as dictated by the particular application for the operation of an integrated circuit (IC) 108. The opposing bottom surface 110 of the substrate 102 defines the outline or perimeter of the bottom of the package 100. According to the invention, a heat channel aperture 112 is provided in the substrate 100. The heat channel aperture 112 preferably provides a direct path from the IC 108 through to the bottom of the package 100. It should be understood that the size and shape of the heat channel aperture 112 and heat channel element 114 may be varied within the scope of the invention as long as its configuration and relationship to the IC 108 provide a direct thermal path between the IC 108 and the bottom of the package 100. In this example, according to the methods further described, the heat channel aperture 112 is larger in area than the IC 108. In the preferred implementation of the invention, the heat channel element size, material, and design details may be adapted for optimal thermomechanical stress, ease of assembly processing, and ease of use according to the final application. This optimization can be made by those skilled in the art using the improvements enabled by this invention.

The heat channel aperture 112 houses a heat channel element 114. Preferably, the heat channel element 114 material is selected for its thermal properties. Ideally, the Coefficient of Thermal Expansion (CTE) of the heat channel element 114 is matched to the CTE of the IC 108. In the preferred embodiment shown in FIG. 1, the heat channel element 114 is made from semiconductor material identical to that used in the construction of the IC 108, i.e., a “dummy” silicon chip in this example, although other materials may also be used as long as a close match is maintained between the IC and heat channel CTEs. Thus, the heat channel element 114, exhibiting optimized thermal, thermomechanical, and processing properties very similar to the IC 108, is used to conduct heat through the heat channel aperture 112 in the less thermally favorable substrate 102. Preferably, the heat channel element 114 and IC 108, are affixed to one another using a suitably strong adhesive 116 with thermal properties as favorable as practical. The heat channel element 114 preferably terminates at the bottom the package 100, more or less defining an interior portion of the bottom surface of the package 100. With continued reference to FIG. 3, an encapsulant 118 seals the IC 108, bond wires, 106, and at least a portion of the top surface 104 of the substrate 102. As is known in the semiconductor package art, in general the encapsulant 118 defines the top and sides of the package 100. The encapsulant 118 may also seal a portion of the heat channel aperture 112 as shown. The heat channel element may also be made of a silicon material which is electrically conductive, in which case there may be electrical connections between the substrate and the heat channel element. The bottom surface 110 of the substrate 102 typically includes attachment points 120 in order to facilitate the attachment of solder balls 122 (not part of the package 100) commonly used to affix the package 100 to a PCB 124. The bottom surface of the heat channel element 114 also includes similar solder ball 122 attachment points 120. Preferably, the heat channel element 114 is masked and patterned using processes similar or identical to those used for the substrate 102. Thus, the mechanical and thermal bond between the package 100 and PCB 124 (not part of the package 100) may be completed using common reflow processes ordinarily used in semiconductor apparatus assembly.

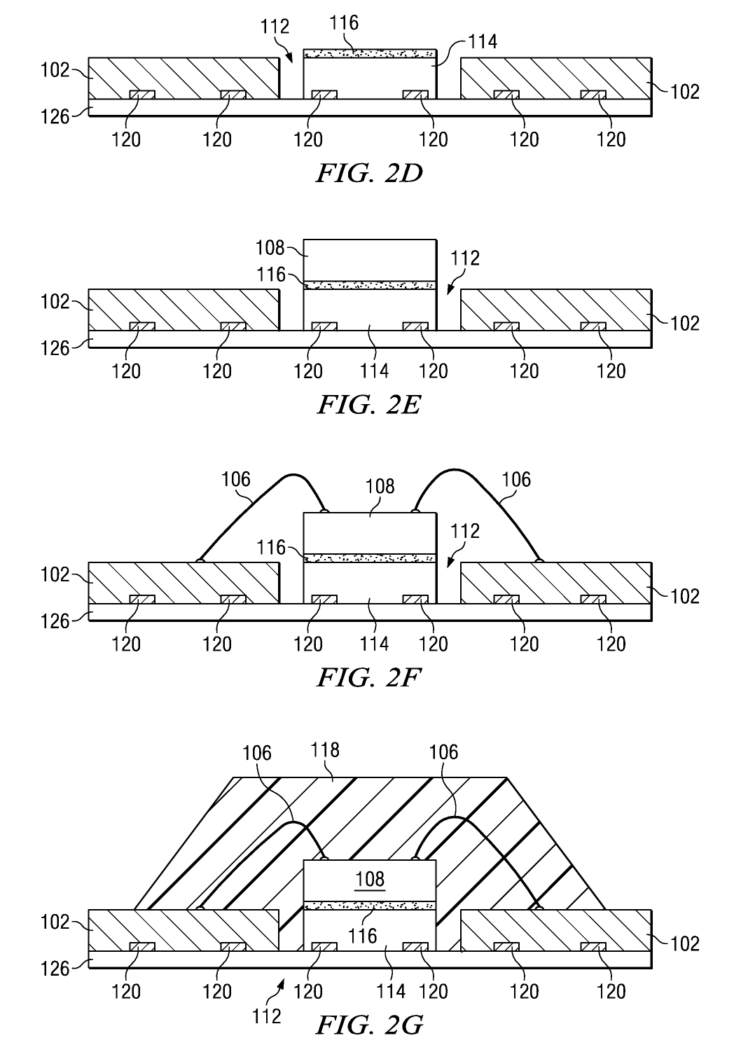

Now referring primarily to FIGS. 2A through 21, a series of cut-away side views is used to illustrate the steps in an example of a preferred method of practicing the invention. It should be apparent to those knowledgeable and skillful in the relevant arts that the description demonstrates the practice of the principles of the invention and is not necessarily exhaustive of all possible variations within the scope of the invention, although some alternative embodiments are also noted.

FIG. 2A is a cut-away side view showing an early step in a method of manufacturing a BGA package according to a preferred embodiment of the invention. A substrate 102 is provided with a heat channel aperture 112 according to the design requirements of the package and particularly according to the configuration of the IC to be contained therein. It should be apparent to those reasonably familiar with the arts that the substrate 102 ordinarily has solder ball attachment points or pads 120 patterned for receiving solder balls.

As shown in the example of FIG. 2B, a further step in the preferred method of manufacturing a BGA according to the invention includes applying a tape 126 or similar temporary holding structure to the underside of the substrate 102. The use of tape 126 or other temporary holding techniques known in the arts for package assembly provides flexibility in the manufacturing process enabling the use of heat channel apertures 112 and heat channel elements 114 of various configurations independent of one another, and independent of the geometry of the IC 108. Continuing to FIG. 2C, it can be seen that the heat channel element 114 is placed atop the tape 126 in the heat channel aperture 112. In this example the heat channel element 114 constitutes a “dummy die” approximating the size and material, e.g., primarily silicon, of the IC to be installed in the package. The heat channel element 114 is preferably equipped with an internal metallic layer and solder patterning similar to that ordinarily used in the arts for ICs or packages to provide solder ball attachment points 120. One possible variation within the scope of the invention is for the heat channel element to have a dielectric material added on top of the metallic layer using an additive or subtractive process, so that the solder ball attachment terminals are defined by the openings in the dielectric material, as is commonly used in the art. One possible design of this patterning layer would be to provide a match of the pattern and pitch of the solder ball patterning on the bottom of the package substrate, so that the solder ball attachment process is common to the two. An adhesive material 116 is preferably placed atop the heat channel element 114, FIG. 2D. The adhesive material 116 may be an adhesive familiar in the arts and is preferably selected insofar as practical for its thermal and thermomechanical compatibility with the heat channel element 114 and IC 108 as well as for its adhesive properties. FIG. 2E depicts the addition of the IC 108 to the surface of the heat channel element 114. It can be seen in FIG. 2E that the heat channel aperture 112 in the preferred embodiment shown is larger than the IC 108, and that the heat channel element 114 is of approximately the same planar dimensions as the IC 108. The exact planar dimensions and thickness of the heat channel element 114 and heat channel aperture 112 may vary within the scope of the invention. For instance, in some cases it may be desirable to make the heat channel aperture and/or heat channel element larger in relationship to the IC than shown, or to make either or both the heat channel aperture and heat channel element smaller than the footprint of the IC. Additionally, it should be recognized that the heat channel element may be made thinner or thicker in relation to the substrate. In general, a heat channel element having a larger planar area enhances thermal performance and bringing the top of the IC closer to the level of the top surface of the substrate improves wirebond flexibility. Additionally, one preferred implementation of the invention provides patterning of the solder ball attachment points on the heat channel element matched to those of the substrate, so that the solder balls may be attached to the entire bottom surface of the package in the same assembly process step. Various configurations within the scope of the invention may be determined without undue experimentation by those reasonably skilled and knowledgeable in the applicable arts.

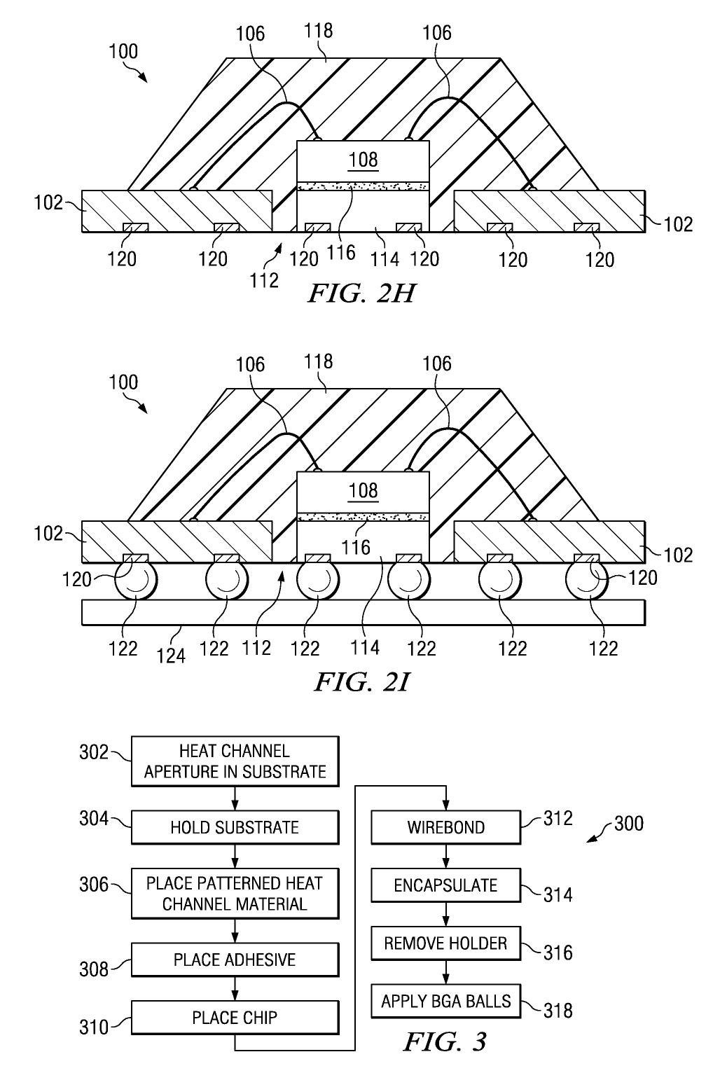

As shown in FIG. 2F, wirebonds 106 between the IC 108 and the substrate 102 may be made in the usual way prior to encapsulation, FIG. 2G, with mold compound 118. Removal of the tape 126 exposes the bottom surface of the package 100, FIG. 2H, where the substrate 102 and heat channel element 114 alike have solder ball attachment points 120. Referring finally to FIG. 21, an example of a method of using a BGA package 100 according to the invention is shown in which the package 100 is attached to a PCB 124 using solder balls 122. It should be appreciated that the solder balls 122 are located at the solder ball attachment points 120 prepared at the substrate 102, and at heat channel element 114 as well.

FIG. 3 is a process flow diagram showing an alternative view of the steps in a preferred method of assembling a BGA according to the invention. The substrate is provided with a heat channel aperture 302. Tape is applied underneath the substrate to hold the structure in order to facilitate the assembly process 304. Other means could be used to align the components during assembly such as a jig or other mechanical contrivance for holding the substrate and/or the heat channel element in place. The heat channel element is placed 306 within the heat channel aperture. Die attach adhesive is placed 308, so that it is positioned between the heat channel element and the IC. The IC is placed 310 adjacent to the heat channel element. The IC is wirebonded 312 to the appropriate substrate contacts. The IC assembly is encapsulated 314 as is known in the arts to form the body of the package. The holding means is removed from the substrate 316 after the package is endowed with sufficient rigidity to maintain the components in alignment. Ultimately, solder balls may be attached 318 to the patterned substrate surface and patterned heat channel element surface for making a secure mechanical and thermal connections using the invention.

The methods and apparatus of the invention provide one or more advantages including but not limited to improving heat dissipation in packaged semiconductor devices using techniques compatible with economical assembly processes. While the invention has been described with reference to certain illustrative embodiments, those described herein are not intended to be construed in a limiting sense. For example, variations or combinations of steps in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

1. A BGA package comprising:
an IC operably coupled to a substrate, the substrate having a top surface and a bottom surface defining the perimeter of the bottom of the package;
an encapsulant encapsulating the IC and at least a portion of the top surface of the substrate, the encapsulant defining the top and sides of the package;
wherein the substrate further comprises a heat channel aperture for receiving heat channel element, the heat channel element having a surface proximal to the IC and having a patterned opposing surface defining at least an interior portion of the bottom surface of the package and coupling to solder balls.

2. A BGA package according to claim 1 wherein the heat channel element comprises material having thermal properties similar to the thermal properties of the IC.

3. A BGA package according to claim 1 wherein the heat channel element comprises material having mechanical properties similar to the mechanical properties of the IC.

4. A BGA package according to claim 1 further comprising an adhesive material disposed between the top surface of the heat channel element and the bottom surface of the IC.

5. A BGA package according to claim 1 wherein the heat channel element and IC comprise silicon.

6. A BGA package according to claim 1 wherein the heat channel aperture and heat channel element are of approximately the same area as the surface of the IC.

7. A BGA package according to claim 1 wherein the heat channel aperture is of a larger area than the surface of the IC.

8. A semiconductor device comprising:
a PCB having solder balls operably coupled to a BGA package, the BGA package further comprising:
an IC operably coupled to a semiconductor substrate, the substrate having a top surface for receiving the IC and a bottom surface defining the perimeter of the bottom of the package;
an encapsulant encapsulating the IC and at least a portion of the top surface of the substrate, the encapsulant substantially defining the top and sides of the package;
wherein the substrate farther comprises a heat channel aperture for receiving heat channel element, the heat channel element having a surface proximal to the IC and having a patterned opposing surface defining at least an interior portion of the bottom surface of the package and coupling to solder balls.

9. A semiconductor device according to claim 8 wherein the heat channel element comprises material having thermal properties similar to the thermal properties of the IC.

10. A semiconductor device according to claim 8 wherein the heat channel element comprises material having mechanical properties similar to the mechanical properties of the IC.

11. A semiconductor device according to claim 8 further comprising an adhesive material disposed between the top surface of the heat channel element and the bottom surface of the IC.

12. A semiconductor device according to claim 8 wherein the heat channel element and IC comprise silicon.

13. A semiconductor device according to claim 8 wherein the heat channel aperture and heat channel element are of approximately the same area as the surface of the IC.

14. A semiconductor device according to claim 8 wherein the heat channel aperture is of a larger area than the surface of the IC.

15. A method for assembling a BGA package comprising the steps of:
providing a substrate with a heat channel aperture;
patterning a surface of a heat channel element for solder ball attachment;
placing the heat channel element in the heat channel aperture, the heat channel element having a patterned surface for receiving solder balls and an opposing surface for receiving an IC;
placing an IC adjacent to the surface of the heat channel element; operably coupling the IC to the heat channel element;
encapsulating the IC; and
thereby providing a direct heat path from the IC to the patterned surface of heat channel element.

16. A method for assembling a BGA package according to claim 15 further comprising the step of attaching solder balls to the patterned surface of the heat channel element.

17. A method for assembling a BGA package according to claim 15 further comprising the step of holding the substrate and heat channel element in their relative positions until the completion of the step of encapsulating the IC.

18. A method for assembling a BGA package according to claim 15 further comprising the step of taping the substrate and heat channel element in their relative positions until the completion of the step of encapsulating the IC.

19. A method for assembling a BGA package according to claim 15 further comprising the step of providing a heat channel element having the same coefficient of thermal expansion as the IC.
